(19) United States
(12) Patent Application Publication
(10) Pub. No.: US 2006/0284290 A1
(43) Pub. Date: Dec. 21, 2006

(54) Chip-package structure and fabrication process thereof

(76) Inventor: Joseph Cheng, TaoYuan (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/154,694

(22) Filed: Jun. 17, 2005

(51) Int. Cl. H01L 23/495; H01L 21/00

(52) U.S. Cl. 257/676; 438/123; 257/787; 438/127; 257/E23.061

(57) ABSTRACT

The present invention discloses a chip-package structure and a fabrication process thereof, wherein a mount board is used as a support part, which is removed after completing the chip-package process, in order to promote the planarity, firmness and reliability of the entire package structure, to reduce the height of the entire package structure, to apply to the packaging of many kinds of semiconductors and to be used for various purposes.

### BACKGROUND OF THE INVENTION

1. Field of the Invention

The present invention relates to a chip-package structure and a fabrication process thereof, particularly to a chip-package structure having a superior planarity and a fabrication process thereof.

2. Description of the Related Art

With the fast functional promotion of the computer, communication, and network products, the semiconductor technology has to meet the demand that the product should be portable, lightweight, slim, miniature, and diversified, which also drives the chip-package industry to advance toward a slim, miniature, lightweight, high-power, high-density, and high-precision fabrication process. Besides, the electronic packaging also has to provide the signal-transferring, power-supplying, heat-dissipating, and structure-protecting functions for the electronic products in high reliability.

At present, when a circuit board is fabricated, elements are soldered to the circuit board one by one; thus, the coplanarity of the entire circuit board has much influence on the reliability of the elements.

Therefore, the present invention proposes a chip-package structure and a fabrication process thereof to overcome the above-mentioned problems.

### SUMMARY OF THE INVENTION

The primary objective of the present invention is to provide to a fabrication process of a chip-package structure, wherein a mount board is used as a support part, and the packaged elements are installed thereon, and then, the mount board will be removed in a posterior step, in order to promote the planarity and firmness of the package structure, increase the reliability in the chip-package process, and apply the superior planarity thereby to circuit boards demanding high coplanarity.

Another objective of the present invention is to provide to a chip-package structure and a fabrication process thereof, wherein a stack structure can be formed via sequentially building up the structures in order to fabricate a multi-layer circuit board, and which can be applied to the package of many kinds of semiconductors.

Yet another objective of the present invention is to provide to a mount board, which can decrease the height of the chip-package structure, and wherein in contrast with several hundred micrometer thickness of the conventional mount board, the thickness of the mount board of the present invention can be lowered to as thin as only several micrometers, so that the height of the entire chip-package structure is obviously reduced.

To achieve the aforementioned objectives, the present invention proposes a fabrication process of a chip-package structure. Firstly, a mount board is provided, and a patterned film and a film are separately formed on the top and the bottom surfaces of the mount board, and multiple patterned through trenches are formed on the mount board via the mask of the patterned film; next, at least one electrically-conductive layer is formed on the patterned through trenches, and the electrically-conductive layer is divided into multiple chip-support zones, and multiple electrical-contact zones isolated from or connected to each other; next, the patterned film and the film are removed; then, at least one chip is installed on each chip-support zone, and the chip is separately electrically connected to the electrical-contact zones; next, an encapsulation resin body, which overlays the electrically-conductive layer and the chip, is formed over the mount board; next, the mount board is removed; and lastly, the entire chip-package structure is cut by each individual chip into several chip-package structures.

Based on the abovementioned fabrication process, the present invention proposes a chip-package structure, which comprises a chip-support substrate and multiple electrical contacts disposed along the perimeter of the chip-support substrate and isolated from/connected to each other. The chip-support substrate or the electrical contact is composed of at least one electrically-conductive layer, and a patterned through trench is formed on the electrically-conductive layer in order to separate the chip-support substrate and the electrical contacts. At least one chip is installed on the chip-support substrate, and the chip is electrically connected to the electrical contacts. Further, an encapsulation resin body is formed over the electrically-conductive layer to overlay the chip with the bottom surface of the electrically-conductive layer exposed.

The present invention also proposes another fabrication process of a chip-package structure. Firstly, a mount board is provided, and a first patterned film and a first film are separately formed on the top and the bottom surfaces of the mount board, and multiple first patterned through trenches are formed on the mount board via the mask of the first patterned film; next, at least one electrically-conductive layer is on the first patterned through trenches; next, a second patterned film and a second film are separately formed on the electrically-conductive layer and the first film, and multiple second patterned through trenches are formed on the mount board via the mask of the second patterned film; next, at least one metallic layer is formed on the second patterned through trenches, and the metallic layer is divided into multiple chip-support zones and multiple electrical-contact zones isolated from or connected to each other; next, the first and the second patterned films and the first and the second films are removed; then, at least one chip is installed on each chip-support zone, and the chip is separately electrically connected to the electrical-contact zones; next, an encapsulation resin body, which overlays the electrically-conductive layer, the metallic layer and the chip, is formed over the mount board; next, the mount board is removed; and lastly, the entire chip-package structure is cut by each individual chip into several chip-package structures.

To enable the objectives, technical contents, characteristics, and accomplishments of the present invention to be more easily understood, the embodiments of the present invention are to be described below in detail and in cooperation with the attached drawings.

### BRIEF DESCRIPTION OF THE DRAWINGS

FIG. 1(a) to FIG. 1(h) are section views showing separately each step of a fabrication process of a chip-package structure according to the present invention.

FIG. 2 is a section view of a chip-package structure according to the present invention.

FIG. 3(a) to FIG. 3(h) are section views showing separately each step of another fabrication process of a chip-package structure according to the present invention.

FIG. 4 is a section view of another chip-package structure according to the present invention.

FIG. 5 is a section view of yet another chip-package structure according to the present invention.

FIG. 6 is a section view of still another chip-package structure according to the present invention.

FIG. 7(a) to FIG. 7(j) are section views showing separately each step of yet another fabrication process of a chip-package structure according to the present invention.

FIG. 8 is a section view of further another chip-package structure according to the present invention.

FIG. 9(a) to FIG. 9(j) are section views showing separately each step of still another fabrication process of a chip-package structure according to the present invention.

FIG. 10 is a section view of further yet another chip-package structure according to the present invention.

FIG. 11 is a section view of further still another chip-package structure according to the present invention.

FIG. 12 is a section view of further still another chip-package structure according to the present invention.

### DETAILED DESCRIPTION OF THE INVENTION

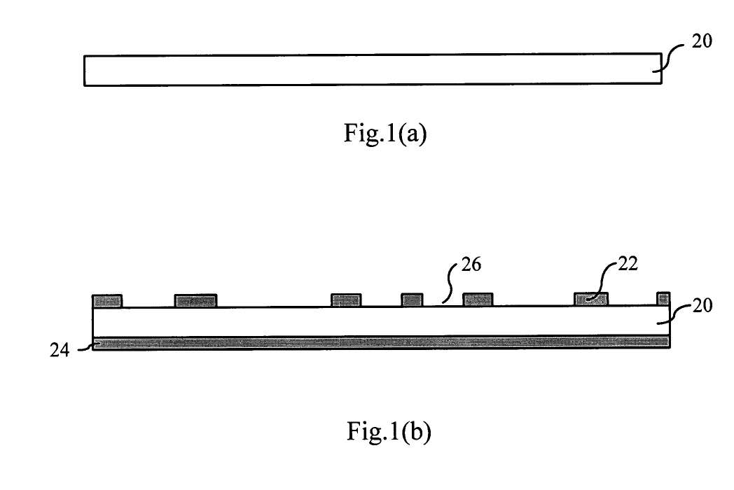

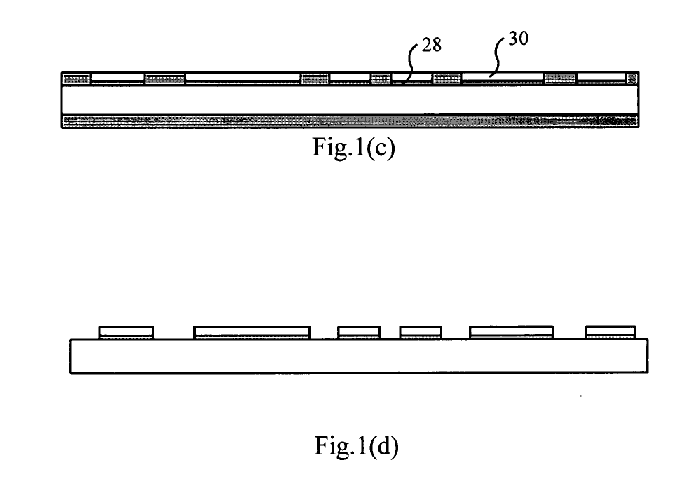

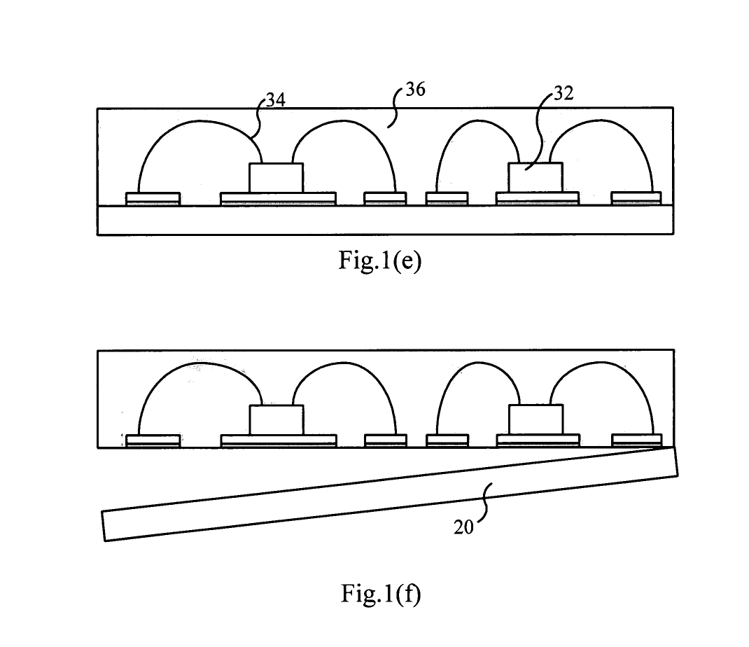

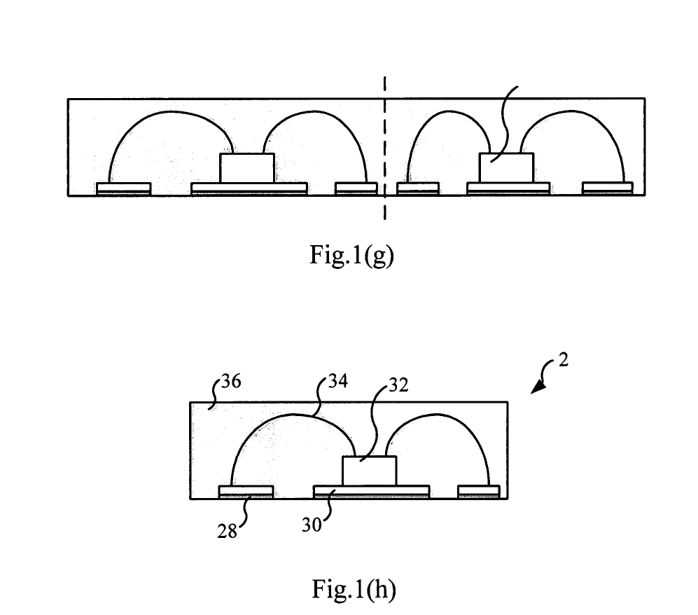

The present invention proposes a chip-package structure and a fabrication process thereof. Refer to from FIG. 1(a) to FIG. 1(h) the section views showing the steps of the fabrication process of the chip-package structure of the present invention. Firstly, a mount board 20, which can be made of a metal, a glass, a ceramic material, or a polymer, is provided, as shown in FIG. 1(a). Next, via a photolithographic process, a patterned film 22 and a film 24 are separately formed on the top and the bottom surfaces of the mount board 20, and multiple patterned through trenches 26 are formed on the mount board 20 via the mask of the patterned film 22, as shown in FIG. 1(b). Next, at least one adhesive layer 28 and at least one electrically-conductive layer 30 are formed inside the patterned through trench 26, as shown in FIG. 1(c), wherein the adhesive layer 28 is installed on the mount board 20 via an adhesive, printing, spin coating, vapor deposition, sputtering, electroless plating, or electroplating method, and wherein the electrically-conductive layer 30 is formed via an adhesive, printing, spin coating, vapor deposition, sputtering, electroless plating, or electroplating method, and wherein the electrically-conductive layer 30 is made of a metallic material or an electrically-conductive material; otherwise, the adhesive layer 28 can be omitted, and the electrically-conductive layer 30 is directly installed inside the patterned through trench 26; the electrically-conductive layer 30 is divided into multiple chip-support zones, and multiple electrical-contact zones isolated from or connected to each other. Next, the patterned film 22 and the film 24 are removed, as shown in FIG. 1(d). For now, the structure in FIG. 1(d) can readily be used as the internal/external-layer circuit of a general circuit board to solve the heat-dissipating problem of the circuit board. Proceeding with the anterior step, at least one chip 32 is installed on each chip-support zone, and the chip 32 is separately electrically connected to the electrical-contact zones via multiple lead lines 34, and an encapsulation resin body 36, which overlays the adhesive layer 28, the electrically-conductive layer 30 and the chip 32, is formed over the mount board 20, as shown in FIG. 1(e). Next, the mount board 20 is removed, as shown in FIG. 1(f). Lastly, as shown in FIG. 1(g), the entire chip-package structure is cut by each individual chip 32 along the dashed line in FIG. 1(g) into several chip-package structures 2 shown in FIG. 1(h).

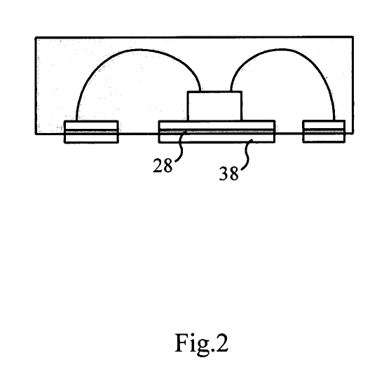

The chip-package structure 2 shown in FIG. 1(h) is to be described below in detail. The chip-package structure 2 comprises a chip-support substrate and multiple electrical contacts disposed along the perimeter of the chip-support substrate and isolated from/connected to each other. The chip-support substrate or the electrical contact is composed of at least one adhesive layer 28 and at least one electrically-conductive layer 30; otherwise, the adhesive layer 28 can also be omitted. A patterned through trench 26 is formed on the adhesive layer 28 and the electrically-conductive layer 30 in order to separate the chip-support substrate and the electrical contacts. At least one chip 32 is installed on the chip-support substrate, and the chip 32 is electrically connected to the electrical contacts. An encapsulation resin body 36 is formed over the electrically-conductive layer 30 to overlay the chip 32 with the bottom surface of the electrically-conductive layer 30 exposed. After the entire chip-package structure has been cut along the dashed line in FIG. 1(g) into several chip-package structures 2 shown in FIG. 1(h), an extra step can be further comprised, wherein at least one bump 38 that is made of a metal or an electrically-conductive material can be formed on the bottom of the adhesive layer 28, as shown in FIG. 2, and in the case that no adhesive layer 28 is formed, the bump 38 is formed on the bottom of the electrically-conductive layer 30.

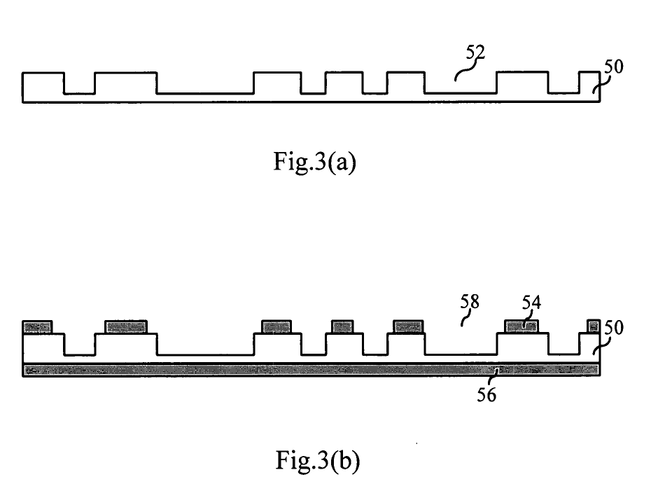

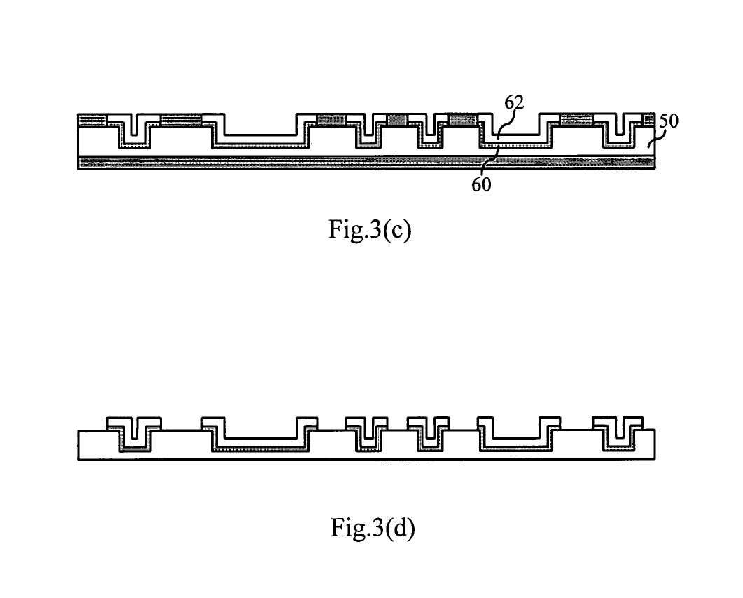

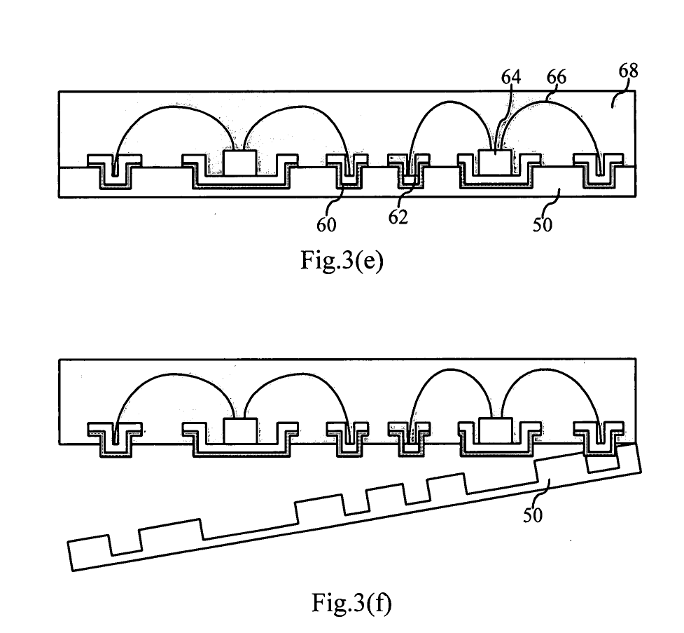

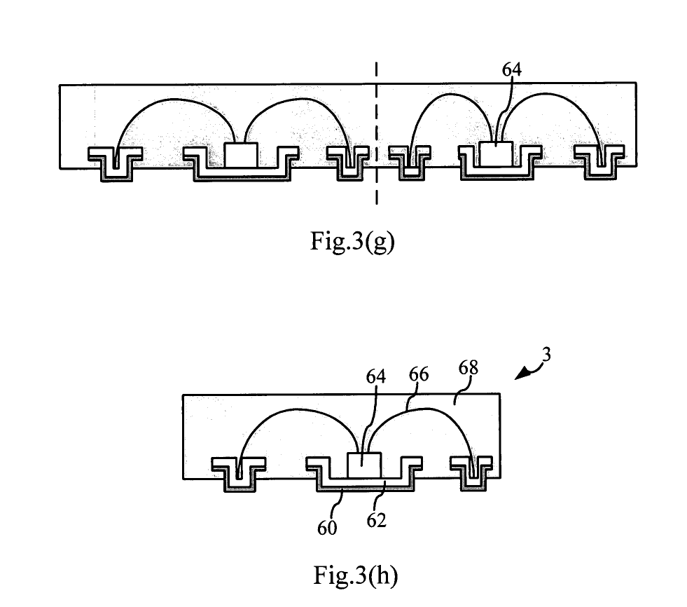

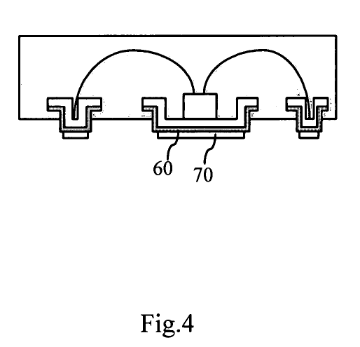

Refer to from FIG. 3(a) to FIG. 3(h) the section views showing the steps of another fabrication process of the chip-package structure proposed by the present invention. Firstly, a mount board 50 is provided, wherein multiple trenches 52 is formed on the mount board 50 at the positions desired by the design via a hole-drilling, high aspect-ratio photolithography, extrusion-forming, or etching method, as shown in FIG. 3(a). Next, a patterned film 54 and a film 56 are separately formed on the top and the bottom surfaces of the mount board 50, and multiple patterned through trenches 58 are formed on the mount board 50 via the mask of the patterned film 54, as shown in FIG. 3(b). Next, at least one adhesive layer 60 and at least one electrically-conductive layer 62 are formed on the patterned through trench 58 and inside the trenches 52, wherein the adhesive layer 60 and the electrically-conductive layer 62 extend to a portion of the surface of the mount board 50, as shown in FIG. 3(c); otherwise, the adhesive layer 60 can be omitted, and only the electrically-conductive layer 62 is installed on the patterned through trench 58 and inside the trenches 52; the electrically-conductive layer 62 is divided into multiple chip-support zones, and multiple electrical-contact zones isolated from or connected to each other. Next, the patterned film 54 and the film 56 are removed, as shown in FIG. 3(d). For now, the structure in FIG. 3(d) can readily be used as the internal/external-layer circuit of a general circuit board to solve the heat-dissipating problem of the circuit board. Proceeding with the anterior step, at least one chip 64 is installed on each chip-support zone, and the chip 64 is separately electrically connected to the electrical-contact zones via multiple lead lines 66, and an encapsulation resin body 68, which overlays the adhesive layer 60, the electrically-conductive layer 62 and the chip 64, is formed over the mount board 50, as shown in FIG. 3(e). Next, the mount board 50 is removed, as shown in FIG. 3(f). Lastly, as shown in FIG. 1(g), the entire chip-package structure is cut by each individual chip 64 along the dashed line in FIG. 3(g) into several chip-package structures 3 shown in FIG. 3(h) with a portion of the adhesive layer 60 and the electrically-conductive layer 62 outcropping from the bottom of encapsulation resin body 68. After the step shown in FIG. 3(h), at least one bump 70 can be formed on the bottom of the adhesive layer 60, as shown in FIG. 4.

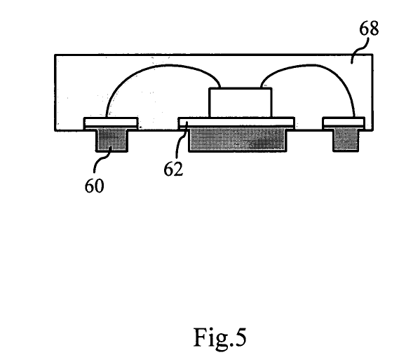

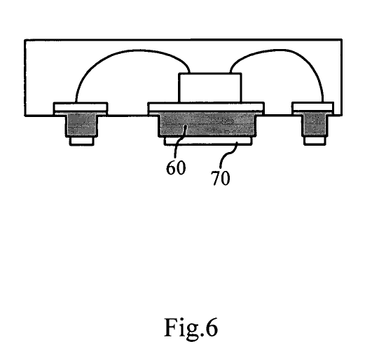

Further, the trenches 52 on the mount board 50 can also be completely filled with the adhesive layer 60 or the electrically-conductive layer 62, which will also extend to a portion of the surface of the mount board 50; in the case that no adhesive layer 60 is formed, the electrically-conductive layer 62 will completely the trenches 52. As shown in FIG. 5, after completing the chip-package process, a portion of the adhesive layer 60 or the electrically-conductive layer 62 will also outcrop from the bottom of encapsulation resin body 68. As shown in FIG. 6, at least one bump 70 can also be formed on the bottom of the adhesive layer 60.

All the material used in the above chip-package structure are the same as those used in the steps shown in from FIG. 1(a) to FIG. 1(h). All the chip-package process mentioned above can be free from installing the adhesive layer 28, 60, and the electrically-conductive layer 30, 62 is directly installed on the mount board 20, 50 in order to form a chip-package structure without the adhesive layer 28, 60. Further, the steps before installing the chip 32, 64 can be repeated in order to form a stack structure.

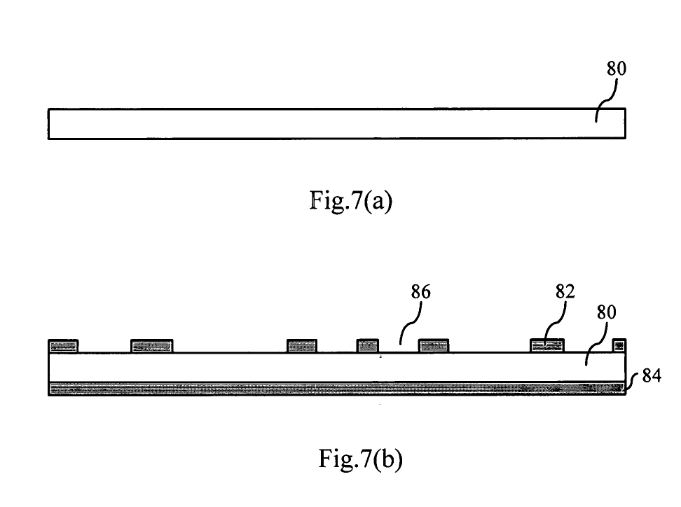

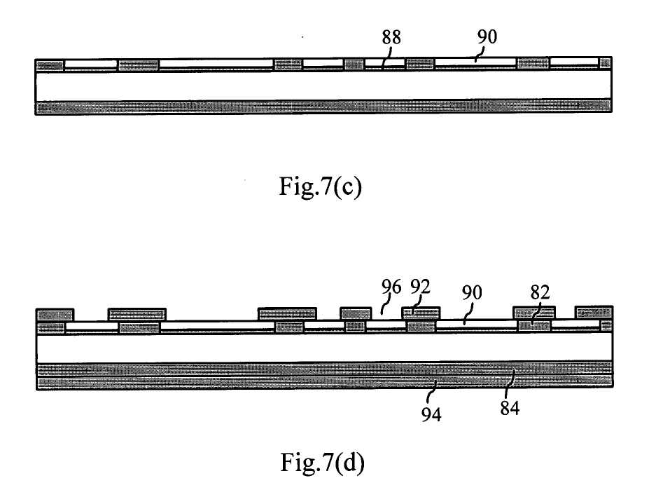

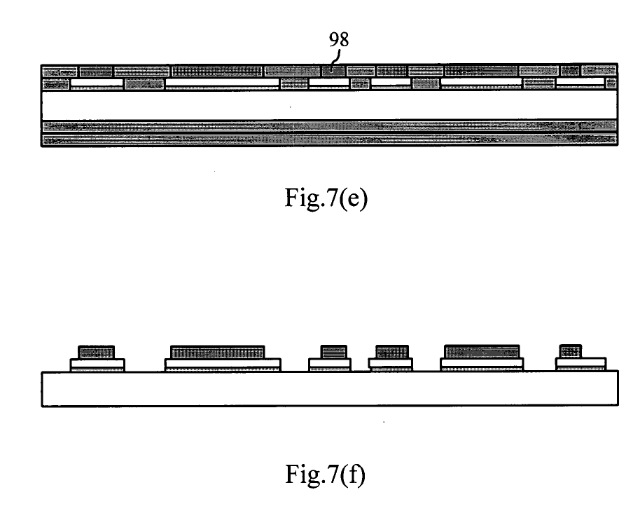

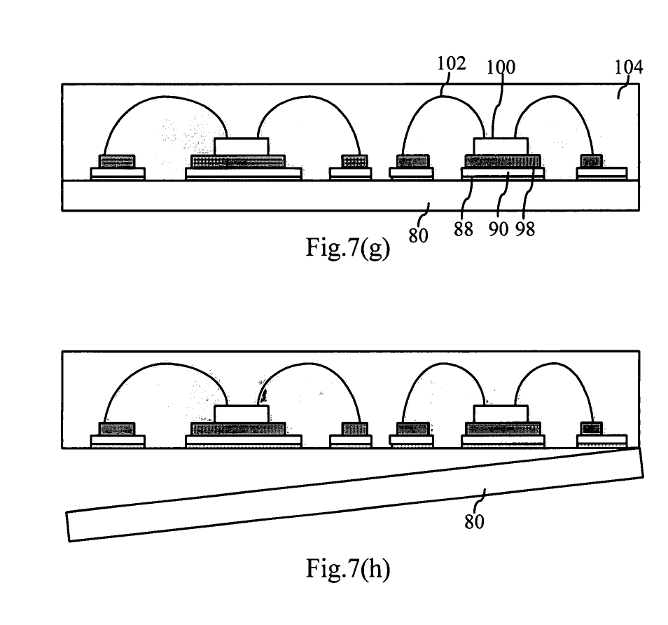

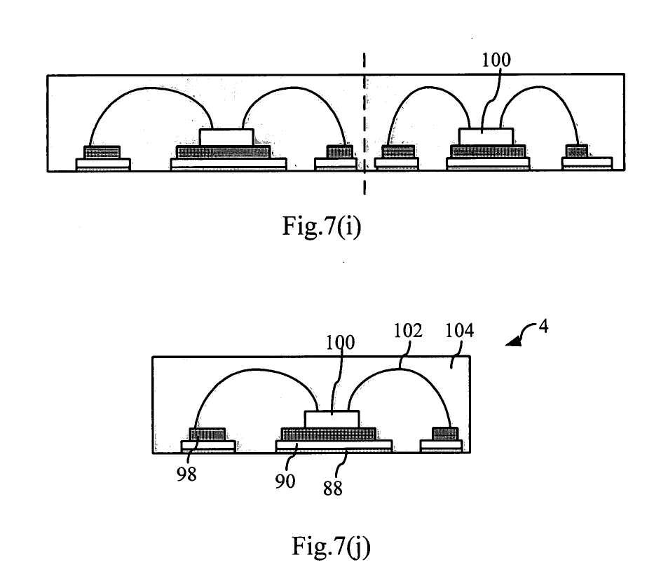

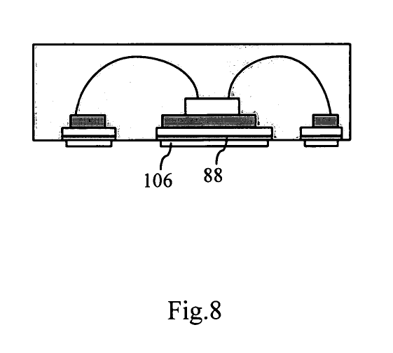

Refer to from FIG. 7(a) to FIG. 7(j) the section views showing the steps of yet another fabrication process of the chip-package structure proposed by the present invention. Firstly, a mount board 80, which can be made of a metal, a glass, a ceramic material, or a polymer, is provided, as shown in FIG. 7(a). Next, via a photolithographic process, a patterned film 82 and a film 84 are separately formed on the top and the bottom surfaces of the mount board 80, and multiple patterned through trenches 86 are formed on the mount board 80 via the mask of the patterned film 82, as shown in FIG. 7(b). Next, at least one adhesive layer 88 and at least one electrically-conductive layer 90 are formed inside the patterned through trench 86, as shown in FIG. 7(c), wherein the adhesive layer 88 is installed via an adhesive, printing, spin coating, vapor deposition, sputtering, electroless plating, or electroplating method, and wherein the electrically-conductive layer 90 is formed via an adhesive, printing, spin coating, vapor deposition, sputtering, electroless plating, or electroplating method; otherwise, the adhesive layer 88 can be omitted, and the electrically-conductive layer 90 is directly installed inside the patterned through trench 86. Next, via a photolithographic process, a patterned film 92 and a film 94 are separately formed above the patterned film 82 and below the film 84, and multiple patterned through trenches 96 are formed on the electrically-conductive layer 90 via the mask of the patterned film 92, as shown in FIG. 7(d). Next, at least one metallic layer 98 is formed inside the patterned through trenches 96; multiple chip-support zones and multiple electrical-contact zones, which are isolated from or connected to each other, are formed on the metallic layer 98, as shown in FIG. 7(e). Next, the patterned film 82, 92 and the film 84, 94 are removed one by one, as shown in FIG. 7(f). Next, at least one chip 100 is installed on each chip-support zone, and the chip 100 is separately electrically connected to the electrical-contact zones via multiple lead lines 102, and an encapsulation resin body 104, which overlays the adhesive layer 88, the electrically-conductive layer 90, the metallic layer 98 and the chip 100, is formed over the mount board 50, as shown in FIG. 7(g). Next, the mount board 80 is removed, as shown in FIG. 7(h). Lastly, as shown in FIG. 7(i), the entire chip-package structure is cut by each individual chip 100 along the dashed line in FIG. 7(i) into several chip-package structures 4 shown in FIG. 7(j). The chip-package structure 4 comprises a chip-support substrate and multiple electrical contacts disposed along the perimeter of the chip-support substrate and isolated from each other. The chip-support substrate or the electrical contact is composed of at least one adhesive layer 88, at least one metallic layer 98 and at least one electrically-conductive layer 90. At least one chip 100 is installed on the chip-support substrate, and the chip 100 is electrically connected to the electrical contacts via the lead lines 102. An encapsulation resin body 104 is formed over the electrically-conductive layer 90 and the metallic layer 98 to overlay the chip 100 with the bottom surface of the adhesive layer 88 exposed. Further, at least one bump 106 can be installed below the adhesive layer 88 to form a chip-package structure shown in FIG. 8.

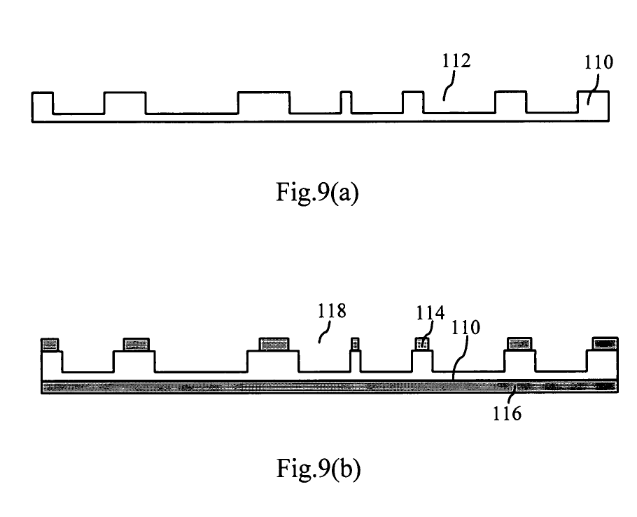

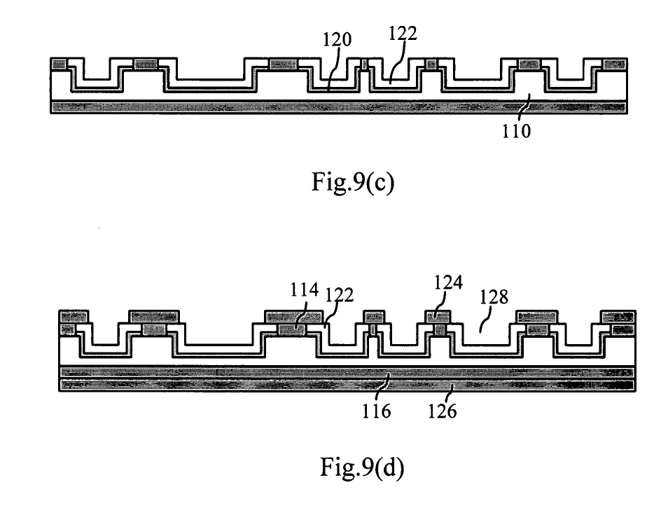

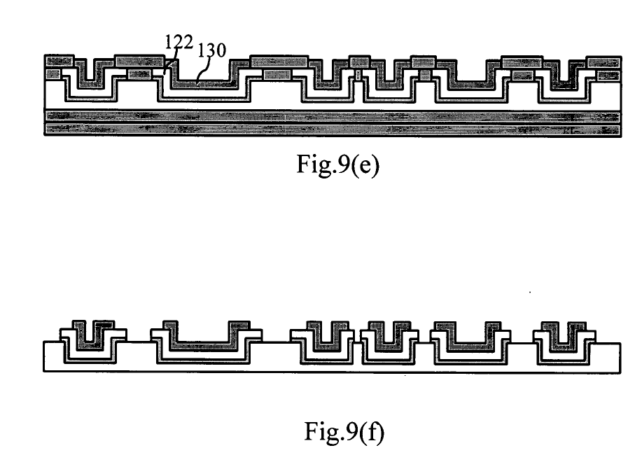

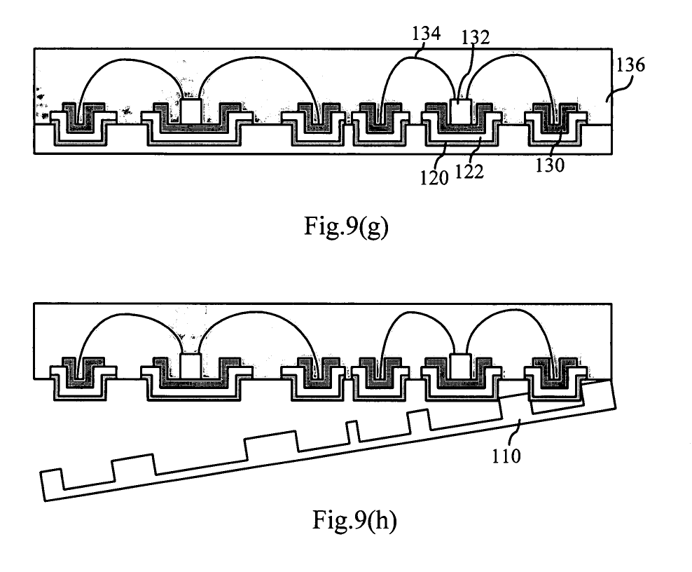

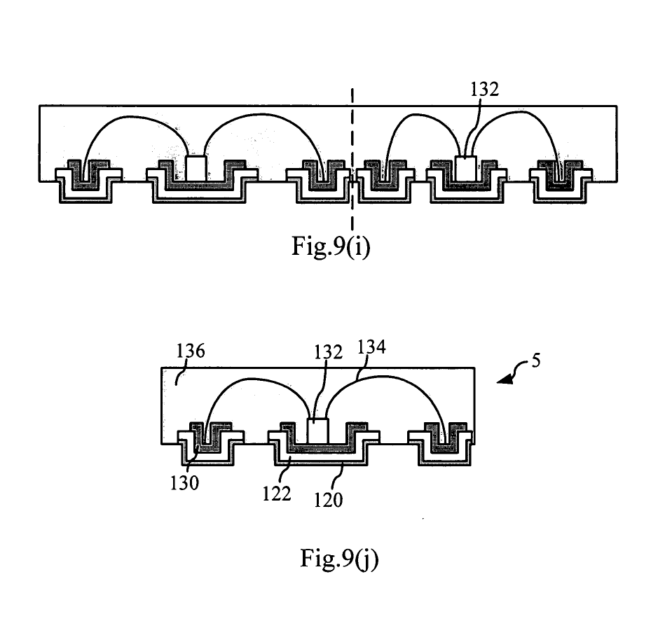

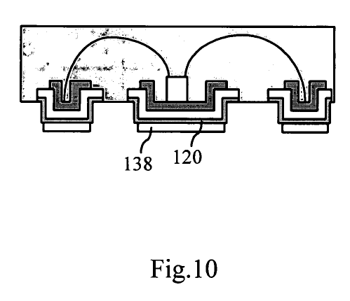

Refer to from FIG. 9(a) to FIG. 9(j) the section views showing the steps of further another fabrication process of the chip-package structure proposed by the present invention. Firstly, a mount board 110 is provided, wherein multiple trenches 112 is formed on the mount board 110 at the positions desired by the design via a hole-drilling, high aspect-ratio photolithography, extrusion-forming, or etching method, as shown in FIG. 9(a). Next, a patterned film 114 and a film 116 are separately formed on the top and the bottom surfaces of the mount board 110, and multiple patterned through trenches 118 are formed on the mount board 110 via the mask of the patterned film 114, as shown in FIG. 9(b). Next, at least one adhesive layer 120 and at least one electrically-conductive layer 122 are formed inside the patterned through trench 118 and on the mount board 110, as shown in FIG. 9(c); otherwise, the adhesive layer 120 can be omitted, and only the electrically-conductive layer 122 is installed inside the patterned through trench 118. Next, via a photolithographic process, a patterned film 124 is formed above the electrically-conductive layer 122 and the patterned film 114 and a film 126 is formed below the film 116, and multiple patterned through trenches 128 are formed on the electrically-conductive layer 122 via the mask of the patterned film 124, as shown in FIG. 9(d). Next, at least one metallic layer 130 is formed inside the patterned through trenches 128 and on the electrically-conductive layer 122; multiple chip-support zones and multiple electrical-contact zones, which are isolated from or connected to each other, are formed on the metallic layer 130, as shown in FIG. 9(e). Next, the patterned film 114, 124 and the film 116, 126 are removed, as shown in FIG. 9(f). Next, at least one chip 132 is installed on each chip-support zone, and the chip 132 is separately electrically connected to the electrical-contact zones via multiple lead lines 134, and an encapsulation resin body 136, which overlays the adhesive layer 120, the electrically-conductive layer 122, the metallic layer 130 and the chip 132, is formed over the mount board 110, as shown in FIG. 9(g). Next, the mount board 110 is removed, as shown in FIG. 9(h). Lastly, as shown in FIG. 9(i), the entire chip-package structure is cut by each individual chip 132 along the dashed line in FIG. 9(i) into several chip-package structures 5 shown in FIG. 9(j). Further, at least one bump 138 can be installed below the adhesive layer 120 to form a chip-package structure shown in FIG. 10.

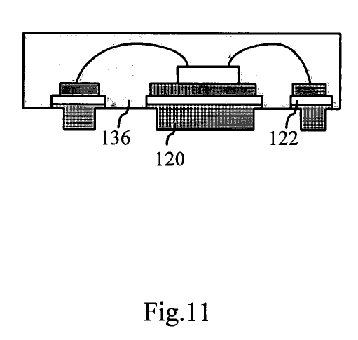

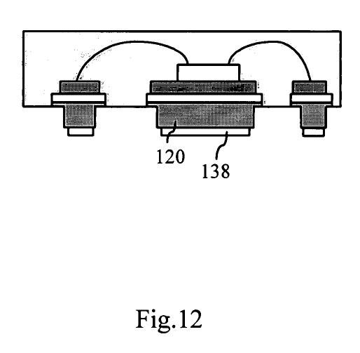

Further, the trenches 112 on the mount board 110 can also be completely filled with the adhesive layer 120 or the electrically-conductive layer 122, which will also extend to a portion of the surface of the mount board 110; in the case that no adhesive layer 120 is formed, the electrically-conductive layer 122 will completely the trenches 112. As shown in FIG. 11, after completing the chip-package process, a portion of the adhesive layer 120 or the electrically-conductive layer 122 will also outcrop from the bottom of encapsulation resin body 136. As shown in FIG. 12, at least one bump 138 can also be formed on the bottom of the adhesive layer 120.

All the material used in the above chip-package structure are the same as those used in the steps shown in from FIG. 1(a) to FIG. 1(h). Further, the steps before installing the chip 100, 132 can be repeated in order to form a stack structure.

The present invention proposes a chip-package structure and a fabrication process thereof. In the present invention, a mount board is used as a support part, and in the succeeding steps, the elements intended to be packaged are installed on the mount board one by one, and in a further posterior step, the mount board is removed, which can promote the planarity, firmness and reliability of the entire package structure. Owing to its planarity, the present invention can be applied to the circuit board demanding a high coplanarity. In the present invention, before chips are installed, the steps before installing the chip 100, 132 can be repeated to form a stack structure in order to fabricate a multi-layer circuit board, so that the present invention can be applied to the packaging of many kinds of semiconductors and can be used for various purposes. In contrast with the mount board with a thickness of several hundred micrometers in the conventional technology, the present invention provides a mount board as thin as few micrometers and can reduce the height of the entire package structure.

The embodiments described above are to clarify the present invention to enable the persons skilled in the art to understand, make and use the present invention but not intended to limit the scope of the present invention. Any equivalent modification and variation without departing from the spirit of the present invention is to be included within the scope of the claims of the present invention appended below.

1-21. (canceled)

22. A chip-package structure, comprising:
a chip-support substrate;
multiple electric contacts, disposed along a perimeter of said chip-support substrate, and isolated from or connected to each other, wherein said chip-support substrate and said electric contacts are composed of an adhesive layer and at least one electrically-conductive layer, and said electrically-conductive layer has a patterned through trench to separate said chip-support substrate and said electric contacts;
at least one chip, disposed on said chip-support substrate, and electrically connected to said electric contacts; and
an encapsulation resin body, disposed above said electrically-conductive layer, and overlaying said chip with the bottom surface of said adhesive layer exposed.

23. (canceled)

24. The chip-package structure according to claim 22, wherein said adhesive layer is made of a metal, an electrically-conductive material, or a polymeric material.

25. The chip-package structure according to claim 22, wherein said chip is electrically connected to multiple said electrical contacts via multiple lead lines.

26. The chip-package structure according to claim 22, wherein said electrically-conductive layer has multiple trenches, and a portion of said electrically-conductive layer outcrops from the bottom of said encapsulation resin body.

27. The chip-package structure according to claim 22, wherein said electrically-conductive layer has multiple under-convexes, and a portion of said under-convexes outcrops from the bottom of said encapsulation resin body.

28. The chip-package structure according to claim 22, which further comprises at least one bump disposed below said electrically-conductive layer and outcropping from the bottom of said encapsulation resin body.

29. The chip-package structure according to claim 22, which further comprises a metallic layer disposed on said electrically-conductive layer, and said patterned trench penetrates said electrically-conductive layer and said metallic layer in order to separate said chip-support substrate and said electric contacts.

30. The chip-package structure according to claim 22, wherein said electrically-conductive layer is made of a metallic material or an electrically-conductive material.

31. The chip-package structure according to claim 28, wherein said bump is made of a metallic material or an electrically-conductive material.
